(19) United States
(12) Patent Application Publication
(10) Pub. No.: US 2010/0007028 A1
(43) Pub. Date: Jan. 14, 2010

(54) DEVICE INCLUDING AN IMIDE LAYER WITH NON-CONTACT OPENINGS AND METHOD

(75) Inventors: Christian Fachmann, Fuernitz (AT); Christoph Ungermanns, Villach (AT); Stefan Gamerith, Villach (AT); Michael Fuchs, Villach (AT)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies Austria AG, Villach (AT)

(21) Appl. No.: 12/171,799

(22) Filed: Jul. 11, 2008

(51) Int. Cl. H01L 23/48; B32B 3/24; B05D 5/12; H01L 21/44; G03F 7/20

(52) U.S. Cl. 257/774; 428/138; 427/123; 430/311; 438/672; 257/E21.575

(57) ABSTRACT

A device including an imide layer with non-contact openings and the method for producing the device. One embodiment provides a substrate on a main surface of the substrate, an imide layer on the metallization layer, at least one contact opening through the imide layer and a plurality of non-contact openings in the imide layer. The non-contact openings are dimensioned to provide for an increased surface area of the imide layer or a surface area of the imide layer which is not reduced by more than 10 percent.

### BACKGROUND

The invention relates to a device including a substrate, a metallization layer and an imide layer, wherein the imide layer is configured to improve an adhesion between a metallization layer and a mold compound, the mold compound used for housing the device.

Devices including a substrate, a metallization layer and an imide layer are used in semiconductor technology, e.g., for power semiconductors. Due to different thermal expansion coefficients, wafers including an imide layer are sensitive to wafer bow effects.

### SUMMARY

One embodiment provides a device including a substrate, a metallization layer on a main surface of the substrate, an imide layer on the metallization layer, at least one contact opening through the imide layer and a plurality of non-contact openings in the imide layer. The non-contact openings are dimensioned to provide for an increased surface area of the imide layer or a surface area of the imide layer which is not reduced by more than 10 percent.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1a illustrates a schematic representation of one embodiment of a surface view of a device.

FIG. 1b illustrates a schematic representation of one embodiment of a cutting plane AB of a device according to FIG. 1a.

FIG. 1c illustrates a schematic representation of one embodiment of a surface view of a device.

FIG. 1d illustrates a schematic representation of one embodiment of a cutting plane CD of a device according to FIG. 1c.

FIG. 2 illustrates a schematic representation of one embodiment of a regular raster of holes.

FIG. 3 illustrates a flow chart of one embodiment of a method for producing a device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

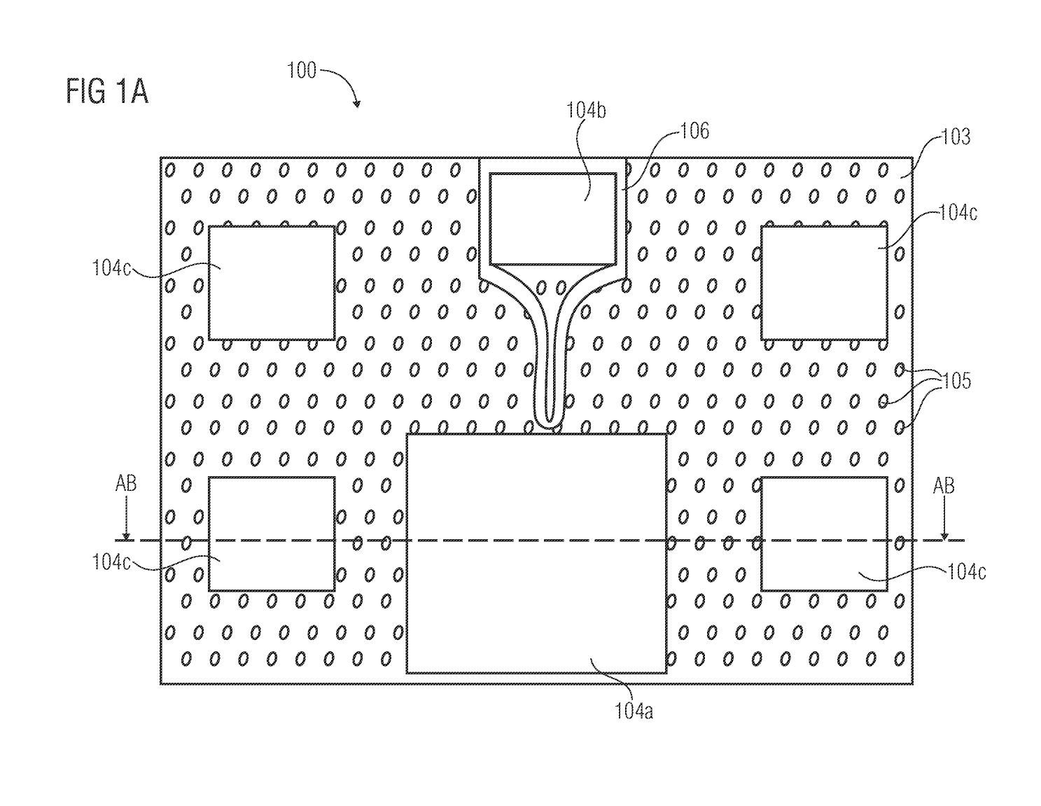

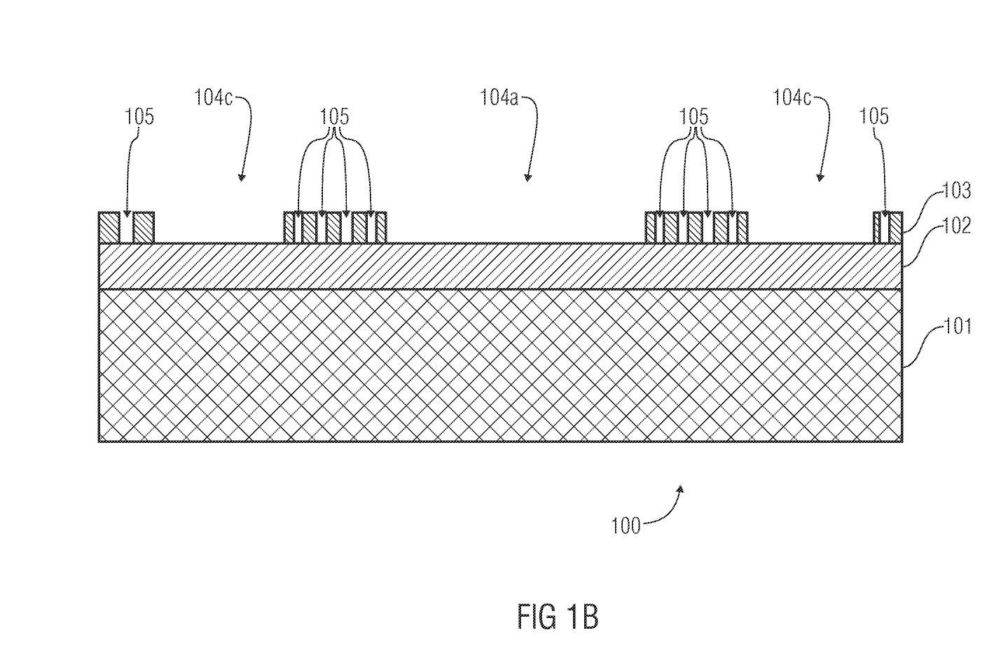

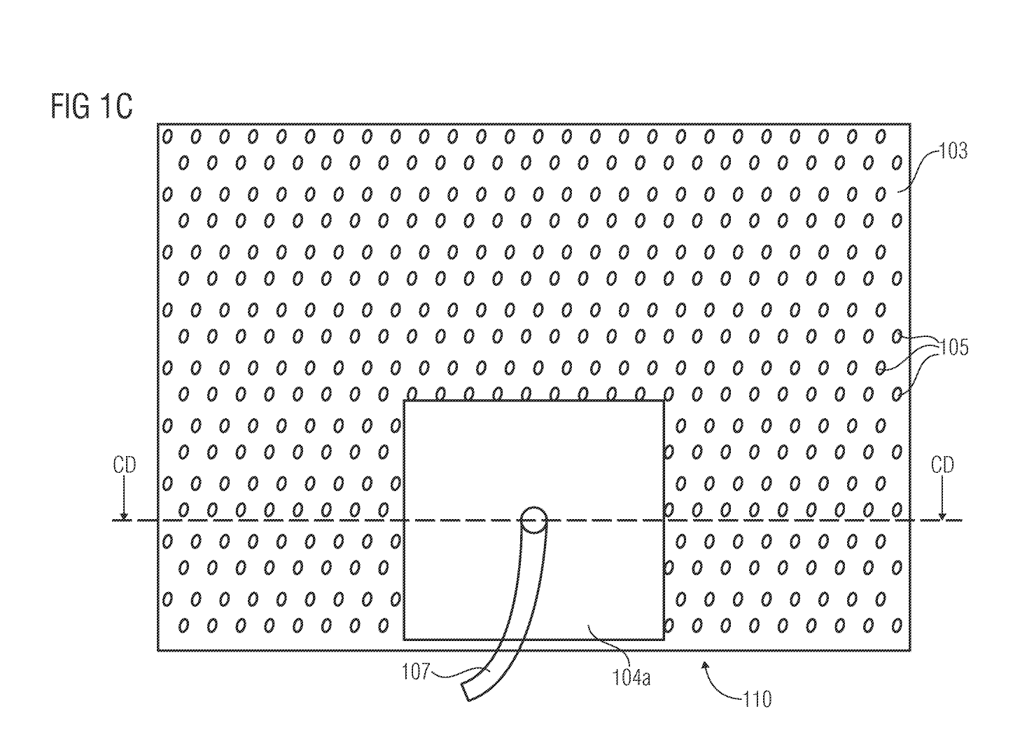

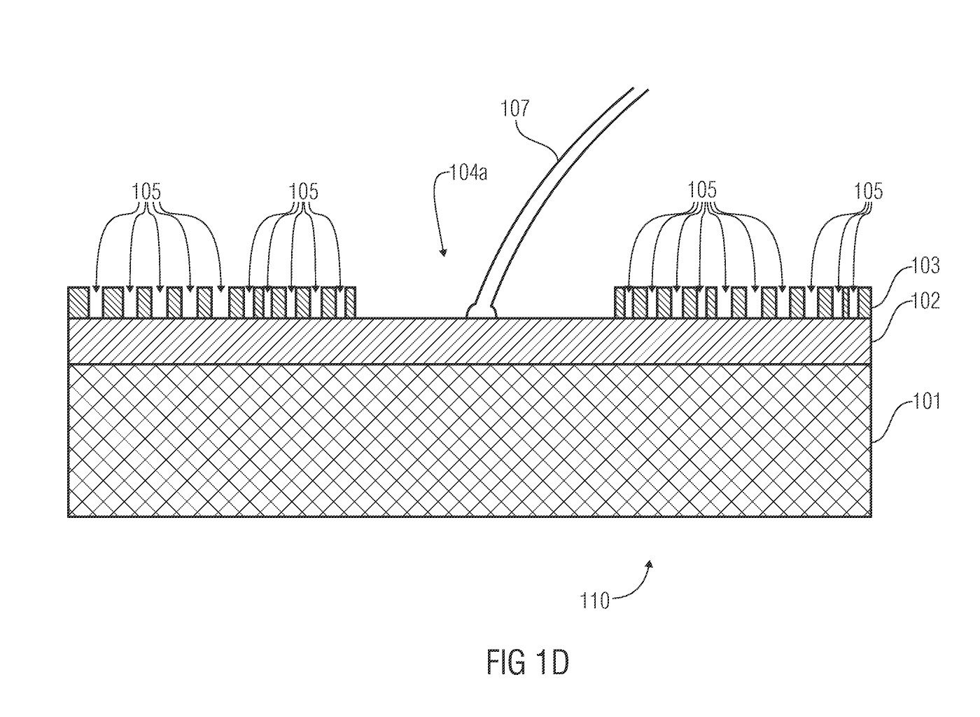

With reference to the accompanying FIGS. 1a to 3, embodiments of a device including a substrate, a metallization layer and an imide layer and a method for producing the device will be hereinafter described.

FIG. 1a illustrates a schematic representation of a surface view of a device. The surface view on the device 100 illustrates a rectangular surface area representing the surface of the device 100, the surface area including different structures. The device 100 includes a substrate below the surface area illustrated in FIG. 1a (not visible in FIG. 1a) and further includes a metallization layer 102 on a main surface of the substrate, which can be seen by looking through the contact openings 104a, 104b, 104c and by looking through a plurality of non-contact openings 105 at the surface of the device 100. The device 100 includes an imide layer 103 on the metallization layer. The imide layer includes the plurality of non-contact openings 105 in same, so that the metallization layer 102 can be seen by looking through the non-contact openings or holes 105, respectively. The contact openings 104a, 104b, 104c are not covered with the imide layer 103. The contact openings 104a, 104b, 104c can be used for contacting the device, for example, by bonding wires to the contact openings 104a, 104b, 104c. A first contact opening 104a may be a source electrode, for example, a second contact opening 104b may be a gate electrode and third contact openings 104c may be other electrodes, e.g., used for testing purposes. The device 100 can be a semiconductor device, for example, a power semiconductor. The non-contact openings 105 are configured to form openings in the imide layer 103 without contacting the metallization layer 102 by an electrical connection to an external terminal through the non-contact openings 105.

The surface view further illustrates an insulation region 106 on an area around the second contact opening 104b to insulate the second contact opening 104b from the first contact opening 104a and from the third contact openings 104c. In this embodiment the insulation region 106 has a frame structure around the second contact opening 104b and a funnel-formed structure towards the first contact opening 104a. This structure may be used for super-junction device designs, for example. However, the insulation region 106 may also have another kind of form, for example, a pure frame around the second contact opening 104b without a funnel-formed structure. It is also possible to form a plurality of insulated electrodes, or contact openings respectively, by using a plurality of non-connected insulation regions 106 or by using an insulation region 106 with non-connected sub-regions respectively. The metallization layer 102 can also be surrounded by an insulation region 106 at borders of the device 100. Also different structures of contact openings 104a, 104c and non-contact openings 105 with or without insulation regions 106 may be formed.

It can be seen from the embodiment according to FIG. 1a that the non-contact openings 105 are distributed in all portions of the imide layer 103, which are arranged on the metallization layer. For providing an improved insulation performance holes may not be distributed in portions of the imide layer on the insulation region. However, in other embodiments non-contact openings 105 may also be distributed in portions of the imide layer on the insulation region.

The non-contact openings 105 or holes, respectively, have a round form, however, may also be differently formed, for example, in a rectangular or hexagonal manner. It can be seen from FIG. 1a that the non-contact openings 105 form a regular raster of holes, wherein the holes 105 are arranged in a hexagonally or triangularly manner, so that each hole has a same distance to its neighboring holes. The non-contact openings 105 extend through the imide layer 103 to the metallization layer 102, so that the metallization layer 102 can be seen in the perspective of FIG. 1a.

The non-contact openings 105 in the imide layer 103 are configured to permit a mold compound to flow into the non-contact openings 105. By this flowing process, the mold compound may stick to the imide layer 103 utilizing a greater adhesion area. The contact area between the imide layer 103 and the mold compound is increased, resulting in a better de-lamination performance. The depth of the imide layer 103 has to be designed relative to the opening area of the holes 105, so as to increase the surface area of the imide layer towards the mold compound. To achieve this design goal, the imide layer 103 may have a thickness in the range of 1 μm to 40 μm, whereas lateral dimensions of the holes 105 may be in the range of 1 μm to 50 μm.

In one embodiment including a raster of non-contact openings 105 or holes, respectively, in the imide layer 103, a volume reduction of the imide layer 103 is caused by the holes 105. A reduced volume of the imide layer reduces wafer bow effects and reduces other negative effects due to the imide layer.

The contact openings 104a, 104b, 104c and the plurality of non-contact openings 105 may be formed, for example, by a photolithographic process or by some other kind of etching process. The contact openings 104a, 104b, 104c and the plurality of non-contact openings 105 may be formed in the same semiconductor processing process, for example. An etching process, for example, may result in different depths of the plurality of non-contact openings 105. A size-sensitive etching process, for example, may be applied for forming the non-contact openings 105.

Other embodiments may include an additional adhesion layer between the metallization layer and the imide layer 103, wherein the non-contact openings 105 may extend through the imide layer 103 and the adhesion layer to the metallization layer 102. The adhesion layer is adapted to improve an adhesion between the metallization layer and the imide layer. The adhesion layer may consist of a dielectric material, e.g., silicon nitride or silicon oxide, while the imide layer is composed of a polyimide chemical group, for example, PI, PBMI, PBI, PBO, PAI, PEI, PISO or PMI being robust against temperature and/or humidity variations.

Other embodiments include a plurality of adhesion layers, wherein the non-contact openings 105 may extend via the imide layer 103 and the plurality of adhesion layers to the metallization layer or wherein the non-contact openings may extend to one of the adhesion layers or to the imide layer. The non-contact openings may also extend to an inner region of the imide layer or to an inner region of one of the adhesion layers without extending to the metallization layer.

A schematic representation of the device 100 according to FIG. 1a in a sectional view can be illustrated in FIG. 1b by cutting the device 100 towards the cutting plane AB.

The device 100 includes a substrate 101, a metallization layer 102 on the main surface of the substrate 101 and an imide layer 103 on the metallization layer 102. The contact openings 104a, 104c can be seen from this sectional view of the device 100. The first contact opening 104a opens the imide layer 103 in the middle of the device 100, wherein the third contact openings 104c open the imide layer 103 on the left and right side of the device 100 while leaving a small margin filled with imide layer 103 corresponding to the cutting plane AB illustrated in FIG. 1a. FIG. 1b also illustrates the non-contact openings 105 with a cut by the cutting plane AB. A mold compound may flow into the non-contact openings 105 to cover and protect the device 100. The contact openings 104a, 104c may be bonded by wires with or without applying solder material for connecting the contact openings 104a, 104c outside of the device 100.

The adhesion layer of other embodiments may be deposited between the metallization layer 102 and the imide layer 103. The adhesion layer may have the same structure as the imide layer with contact openings 104a, 104b, 104c and holes 105 in same regions of the main surface of the substrate.

FIG. 1c illustrates a schematic representation of one embodiment of a surface view of a device. The surface view on the device 110 illustrates a rectangular surface area representing the surface of the device 110, the surface area including different structures. The device 110 is similar to the device 100 according to FIG. 1a and includes a substrate below the surface area illustrated in FIG. 1c (not visible in FIG. 1c) and a metallization layer on a main surface of the substrate, which can be seen by looking through the contact opening 104a and by looking through the plurality of non-contact openings 105 or holes, respectively, at the surface of the device 110. The device 110 further includes an imide layer 103 on the metallization layer. The imide layer includes the plurality of non-contact openings in same, so that the metallization layer can be seen by looking through the non-contact openings 105. The contact opening 104a is not covered with the imide layer. The contact opening 104a is used for contacting the device. In this embodiment the contact opening is contacted by a wire 107 which is configured to form an electrical connection to the metallization layer. The plurality of non-contact openings 105 or holes, respectively, are not contacted by wires 107 as they are not configured for contacting the metallization layer. The non-contact openings 105 may, for example, have lateral dimensions smaller than 50 μm, whereas the contact opening 104a or the plurality of contact openings 104a, respectively, may have larger dimensions than the non-contact openings 105.

A schematic representation of the device 110 according to FIG. 1c in a sectional view can be illustrated in FIG. 1d by cutting the device 110 towards the cutting plane CD.

The device 110 includes a substrate 101, a metallization layer 102 on the main surface of the substrate 101 and an imide layer 103 on the metallization layer 102. The contact opening 104a can be seen from this sectional view of the device 100. The contact opening 104a is bonded or soldered by the wire 107 for connecting the metallization layer or a region of the metallization layer to an outside terminal. FIG. 1d also illustrates the non-contact openings 105 not contacted by a bonding wire 107 with a cut by the cutting plane CD. A mold compound may flow into the non-contact openings 105 to cover and protect the device 110. The device 110 may comprise, for example, a number of non-contact openings 105 in a range of some hundreds to some ten thousands.

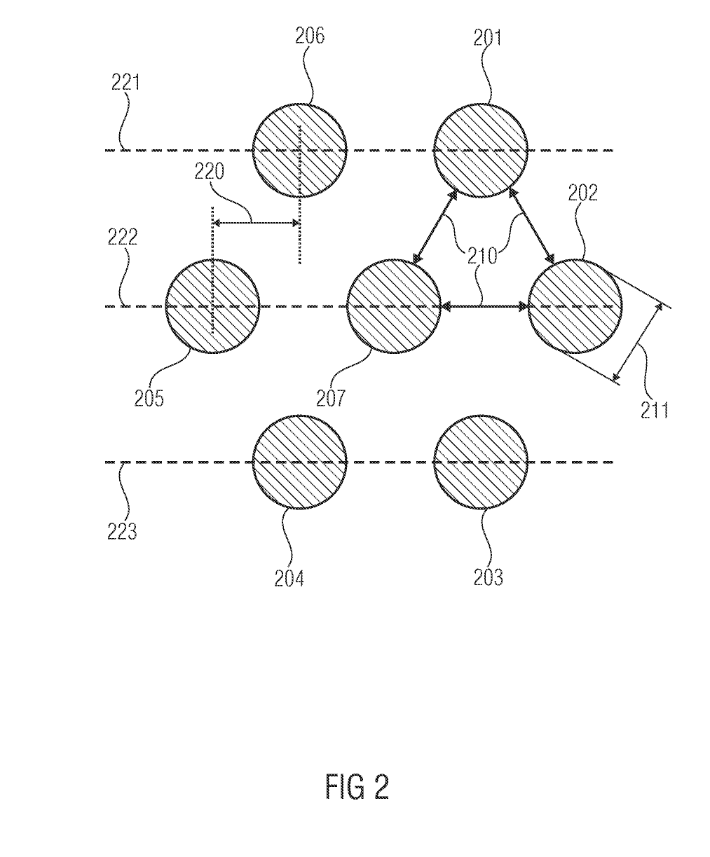

FIG. 2 illustrates a schematic representation of one embodiment of a regular raster of holes. FIG. 2 illustrates a first hole 201, a second hole 202, a third hole 203, a fourth hole 204, a fifth hole 205, a sixth hole 206 and a seventh hole 207. The seven holes illustrated in FIG. 2 correspond to the non-contact openings 105 or holes, respectively, illustrated in FIGS. 1a and 1b. While the holes may have a round, rectangular or hexagonal form, FIG. 2 illustrates an embodiment with a representation of holes having a round form. The holes are arranged on a raster including rows of holes. A lateral dimension of the non-contact openings 105 may be in the range of twice the thickness of the imide layer, for example.

FIG. 2 illustrates an example showing three rows, a first row 221, a second row 222 and a third row 223. The first hole 201 and the sixth hole 206 are arranged on the first row 221. The second hole 202, the seventh hole 207 and the fifth hole 205 are arranged on the second row. The third hole 203 and the fourth hole 204 are arranged on the third row 223. Adjacent rows of holes are offset with respect to each other. An offset 220 is illustrated between the fifth hole 205 and the sixth hole 206. In this embodiment, the offset 220 is equal for adjacent holes, so that a regular raster is generated forming a hexagon or a triangle. A hexagon is formed by the first to sixth holes 201 to 206, while a triangle is formed by the first, second and seventh holes 201, 202, 207. In this embodiment, a distance 210 between neighboring holes 201, 202, 207 is equal to a lateral dimension 211 corresponding to a diameter of one of the holes 202. The distance 210 may be 30 μm to 35 μm, for example, corresponding to a lateral dimension 211 of 30 μm to 35 μm, for example. In one embodiment, holes are provided with a sufficiently small diameter to optimally increase the contact area of the imide layer.

It is also possible to utilize different kinds of rasters, for example, with a non-regular offset 220 or with distances 210 unequal to lateral dimensions 211 or with a random or pseudo-random distribution of holes. Also different sizes of holes, e.g., with different diameters of individual holes or different forms (round, triangular, hexagonal etc.) of individual holes can be used.

Chip layout designs using non-contact openings, for example, using optimized hexagonal raster holes, may provide imide coverages in the range of 28% to 36%, that is a reduction in imide coverage by a factor of greater than two versus a layout without using holes.

In one or more embodiments, non-contact openings or holes, respectively, may have diameters in the range of 25 μm to 35 μm, for example. A (gross) hole area may be in the range of 5E-04 mm² to 10E-04 mm², for example, providing contact areas in the range of 0.8E-03 mm² to 1.2 E-03 mm² and a relation of contact area versus hole area between 1.3 and 1.8.

For a number of holes chosen to 3500, for example, a relation of contact area to mold area may result in a value of 5.5 to 6 and a contact area gain in the range of 25%.

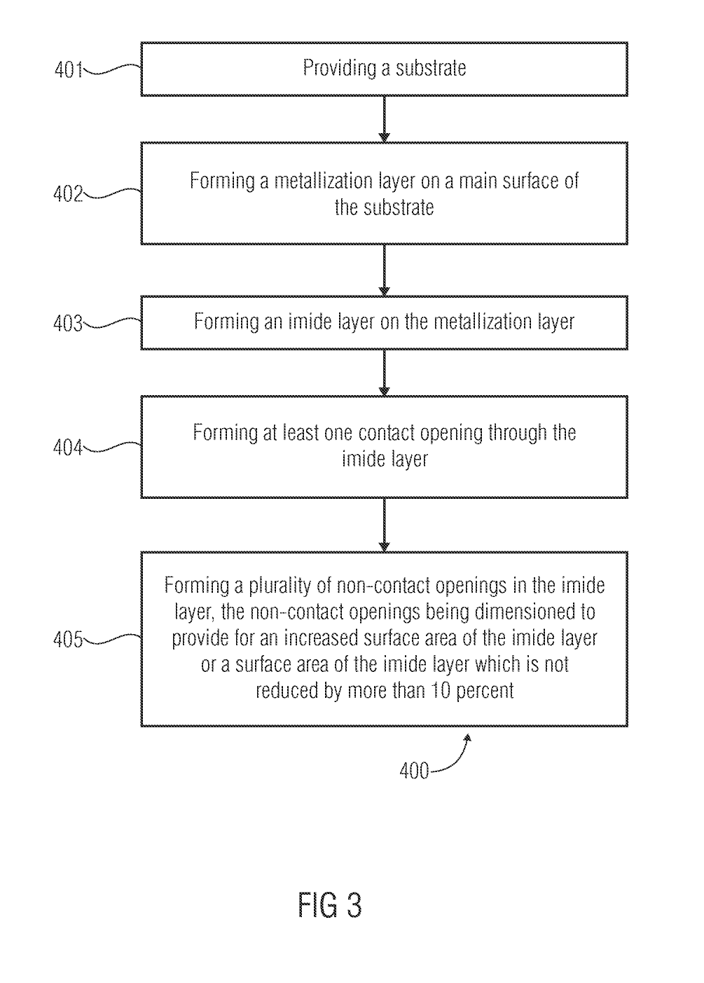

FIG. 3 illustrates a flow chart of one embodiment of a method for producing a device. The method 400 includes five processes: A first process 401 “providing a substrate”, a second process 402 “forming a metallization layer on a main surface of the substrate”, a third process 403 “forming an imide layer on the metallization layer”, a fourth process 404 “forming at least one contact opening through the imide layer” and a fifth process 405 “forming a plurality of non-contact openings in the imide layer, the non-contact openings being dimensioned to provide for an increased surface area of the imide layer or a surface area of the imide layer which is not reduced by more than 10 percent”. The sequence of the processes 401 to 405 is not limited to the sequence illustrated in FIG. 3. For example, the fourth process 404 and the fifth process 405 may be performed in the same processing step, possibly in a single photolithographic or etching processes for manufacturing a semiconductor device. It is also possible to use a different sequence for these processes 401 to 405.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A device comprising:
a substrate;
a metallization layer on a main surface of the substrate;
an imide layer on the metallization layer;
at least one contact opening through the imide layer; and
a plurality of non-contact openings in the imide layer, the non-contact openings being dimensioned to provide for an increased surface area of the imide layer or a surface area of the imide layer which is not reduced by more than 10 percent.

2. The device of claim 1, comprising wherein the non-contact openings are distributed in all portions of the imide layer, arranged on the metallization layer.

3. The device of claim 1, wherein the metallization layer comprises at least two regions electrically insulated from each other by an insulation region, wherein the non-contact openings are not formed in a portion of the imide layer formed on the insulation region.

4. The device of claim 1, comprising wherein the non-contact openings extend through the imide layer to an inner region of the imide layer or to the metallization layer.

5. The device of claim 1, further comprising:
at least one adhesion layer between the metallization layer and the imide layer.

6. The device of claim 5, comprising wherein the non-contact openings extend through the adhesion layer to an inner region of the adhesion layer or extend to the metallization layer.

7. The device of claim 1, wherein the non-contact openings comprise a round, rectangular or hexagonal form.

8. The device of claim 1, comprising wherein the imide layer has a thickness in the range of 1 μm to 40 μm.

9. The device of claim 1, comprising wherein the metallic layer is structured to define source and gate electrodes of a power semiconductor device.

10. The device of claim 1, comprising:
a mold compound arranged on the imide layer and in the non-contact openings.

11. The device of claim 14, comprising wherein the non-contact openings are configured to permit mold compound flow.

12. A device comprising:
a substrate;
a metallization layer on a main surface of the substrate;
an imide layer on the metallization layer;
at least one contact opening through the imide layer; and
a plurality of non-contact openings in the imide layer, the non-contact openings being dimensioned to provide for an increased surface area of the imide layer or a surface area of the imide layer which is not reduced by more than 10 percent,
wherein the non-contact openings form a regular or random raster of non-contact openings.

13. The device of claim 12, wherein the raster comprises rows of non-contact openings, wherein adjacent rows of non-contact openings are offset with respect to each other.

14. The device of claim 12, comprising wherein the non-contact openings are arranged in a hexagonally or triangularly manner, so that each non-contact opening has the same distance to its neighboring non-contact openings.

15. The device of claim 12, comprising wherein lateral dimensions of the non-contact openings are in a range of 1 μm to 50 μm.

16. A device comprising:
a substrate;
a metallization layer on a main surface of the substrate;
an imide layer on the metallization layer, the imide layer having a thickness in a range of 1 μm to 40 μm;
at least one contact opening through the imide layer; and
a plurality of non-contact openings in the imide layer wherein the non-contact openings extend through the imide layer to the metallization layer and have lateral dimensions in the range of 1 μm to 50 μm.

17. The device as claimed in claim 16, further comprising:
an adhesion layer between the metallization layer and the imide layer; and
a mold compound arranged on the imide layer and in the non-contact openings.

18. A device comprising:
a substrate;
a metallization layer on a main surface of the substrate;
an imide layer on the metallization layer;
at least one contact opening through the imide layer wherein an electrical connection to the metallization extends through the contact opening; and
a plurality of non-contact openings in the imide layer not comprising an electrical connection extending therethrough.

19. The device of claim 18, comprising wherein the non-contact openings have lateral dimensions smaller than 50 μm.

20. A method for producing a device, comprising:
providing a substrate;
forming a metallization layer on the main surface of the substrate;
forming an imide layer on the metallization layer;
forming at least one contact opening through the imide layer; and
forming a plurality of non-contact openings in the imide layer, the non-contact openings being dimensioned to provide for an increased surface area of the imide layer or a surface area of the imide layer which is not reduced by more than 10 percent.

21. The method of claim 20, comprising performing the forming of at least one contact opening and the forming of the plurality of non-contact openings in the same process.

22. Method as claimed in claim 20, wherein the at least one contact opening and the plurality of non-contact openings are formed by a photolithographic process.

23. The method of claim 20, further comprising:
forming an adhesion layer between the metallization layer and the imide layer; and
extending the contact openings and the non-contact openings through the adhesion layer to an inner region of the adhesion layer or to the metallization layer.

24. The method of claim 20, further comprising:
forming a mold compound on the imide layer so as to permit the mold compound flow into the holes of the imide layer.

25. The method of claim 22, comprising forming at least one contact opening and the plurality of non-contact openings by an etching process using a same mask for forming the contact openings and the non-contact openings in the imide layer and in the adhesion layer.
